(19) United States
(12) Patent Application Publication
(10) Pub. No.: US 2015/0060994 A1
(43) Pub. Date: Mar. 5, 2015

(54) NON-VOLATILE SEMICONDUCTOR MEMORY DEVICE AND METHOD FOR MANUFACTURING SAME

(71) Applicant: Kabushiki Kaisha Toshiba, Minato-ku (JP)

(72) Inventors: Tatsuya KATO, Mie-ken (JP); Tatsuya Okamoto, Mie-ken (JP)

(73) Assignee: Kabushiki Kaisha Toshiba, Minato-ku (JP)

(21) Appl. No.: 14/162,292

(22) Filed: Jan. 23, 2014

Related U.S. Application Data
(60) Provisional application No. 61/870,972, filed on Aug. 28, 2013.

(51) Int. Cl. H01L 27/115; H01L 29/423

(52) U.S. Cl. CPC H01L 27/11575; H01L 27/1157; H01L 29/4234; H01L 27/11573
USPC 257/326; 438/424

(57) ABSTRACT

According to one embodiment, a non-volatile semiconductor memory device, includes: peripheral transistors including a second element isolation insulating film, a gate electrode, and a diffusion layer region, the second element isolation insulating film being configured to divide the semiconductor layer into at least two second semiconductor regions, the diffusion layer region being formed in the second semiconductor regions to be provided on two sides of the gate electrode; and a sidewall film provided at a side surface of the gate electrode. The second element isolation insulating film has a first portion and a second portion, the second portion is provided on two sides of the first portion, a width of a bottom portion of the first portion in an extension direction of the gate electrode is not more than twice a thickness of the sidewall film at a lower end of the sidewall film.

### CROSS-REFERENCE TO RELATED APPLICATIONS

This application is based upon and claims the benefit of priority from U.S. Provisional Patent Application 61/870,972, filed on Aug. 28, 2013; the entire contents of which are incorporated herein by reference.

### FIELD

Embodiments described herein relate generally to a non-volatile semiconductor memory device and a method for manufacturing the same.

### BACKGROUND

In non-volatile semiconductor memory devices, shrinking of the control gate electrodes and the active regions of the memory cell unit is advancing due to the need to increase the capacity and reduce the cost. Accordingly, the dimensions of the peripheral circuit unit also are being reduced. Thereby, the leak current of the transistors of the peripheral circuit unit may increase, and the transistor characteristics may fluctuate due to the end portions of the gate electrodes being smaller.

### BRIEF DESCRIPTION OF THE DRAWINGS

FIG. 1 is an example of a layout diagram showing NAND flash memory according to a first embodiment;

FIG. 2 is an example of a schematic plan view showing a pattern layout of a memory cell unit according to the first embodiment;

FIG. 3 is an example of a schematic plan view showing transistors of a peripheral unit according to the first embodiment;

FIGS. 4A and 4B are examples of schematic cross-sectional views of the memory cell unit according to the first embodiment; and FIGS. 4C and 4D are examples of schematic cross-sectional views of a transistor of the peripheral unit;

FIG. 5A to FIG. 8D are examples of schematic cross-sectional views showing the manufacturing processes of the non-volatile semiconductor memory device according to the first embodiment;

FIG. 9A to FIG. 11B are examples of schematic plan views showing the manufacturing processes of the non-volatile semiconductor memory device according to the first embodiment;

FIGS. 12A and 12C are examples of schematic plan views showing the manufacturing processes of the non-volatile semiconductor memory device according to the first embodiment; and FIG. 12B and FIG. 12D are examples of schematic cross-sectional views showing the manufacturing processes of the non-volatile semiconductor memory device according to the first embodiment;

FIG. 13A and FIG. 13B are examples of schematic cross-sectional views showing the manufacturing processes of the non-volatile semiconductor memory device according to the first embodiment;

FIG. 14A and FIG. 14B are examples of schematic cross-sectional views showing the manufacturing processes of the non-volatile semiconductor memory device according to the first embodiment;

FIG. 15A and FIG. 15B are schematic plan views showing a manufacturing processes of a non-volatile semiconductor memory device according to a comparative example;

FIG. 16A is an example of a schematic plan view showing a manufacturing processes of a non-volatile semiconductor memory device according to a second embodiment; and FIG. 16B is an example of a schematic cross-sectional view;

FIG. 17A is an example of a schematic plan view showing the manufacturing processes of the non-volatile semiconductor memory device according to the second embodiment; and FIG. 17B is an example of a schematic cross-sectional view;

FIGS. 18A and 18B are an example of a schematic cross-sectional view showing the manufacturing processes of the non-volatile semiconductor memory device according to the second embodiment;

FIGS. 19A and 19B are an example of a schematic cross-sectional view showing the manufacturing processes of the non-volatile semiconductor memory device according to the second embodiment; and

FIG. 20A is an example of a schematic cross-sectional view of the memory cell unit according to a third embodiment; and FIGS. 20B and 20C are examples of schematic cross-sectional views of a transistor of a peripheral unit.

### DETAILED DESCRIPTION

In general, according to one embodiment, a non-volatile semiconductor memory device, includes: a memory cell including a charge storage layer, a control gate electrode, and first semiconductor regions of a semiconductor layer divided in a first direction by a first element isolation insulating film, the first semiconductor regions extending in a second direction intersecting the first direction, the charge storage layer being provided above the first semiconductor regions, the control gate electrode being provided above the charge storage layer; a selection gate transistor including a selection gate electrode disposed above the first semiconductor regions with an insulating film; peripheral transistors including a second element isolation insulating film, a gate electrode, and a diffusion layer region, the second element isolation insulating film being configured to divide the semiconductor layer into at least two second semiconductor regions, the diffusion layer region being formed in the second semiconductor regions to be provided on two sides of the gate electrode; and a sidewall film provided at a side surface of the gate electrode. The second element isolation insulating film has a first portion and a second portion, the second portion is provided on two sides of the first portion, a width of a bottom portion of the first portion in an extension direction of the gate electrode is not more than twice a thickness of the sidewall film at a lower end of the sidewall film.

Embodiments will now be described with reference to the drawings. In the description hereinbelow, there are cases where similar members are marked with like reference numerals; and in such a case, a description is omitted as appropriate for members once described.

### First Embodiment

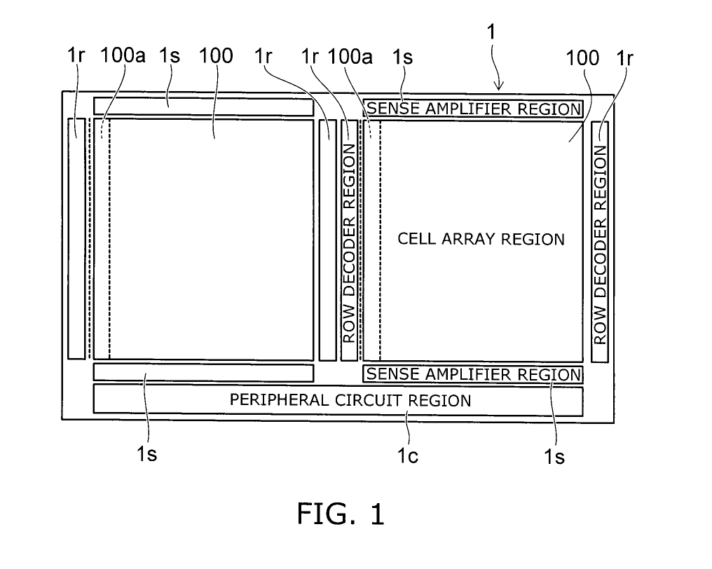

FIG. 1 is an example of a layout diagram showing NAND flash memory according to a first embodiment.

A memory cell unit (a cell array region) 100, a row-direction end portion region 100a of the memory cell unit 100, a sense amplifier region 1s, a row decoder region 1r, and a peripheral circuit region 1c are disposed in the non-volatile semiconductor memory device 1. In the embodiment, the sense amplifier region 1s, the row decoder region 1r, and the peripheral circuit region 1c may be referred to as a peripheral unit 200. The peripheral unit 200 is disposed adjacent to the memory cell unit 100. In the memory cell unit 100, memory strings, in which selection gate transistors are connected at two ends of a column in which nonvolatile memory cell transistors are connected in series and are arranged in a matrix configuration.

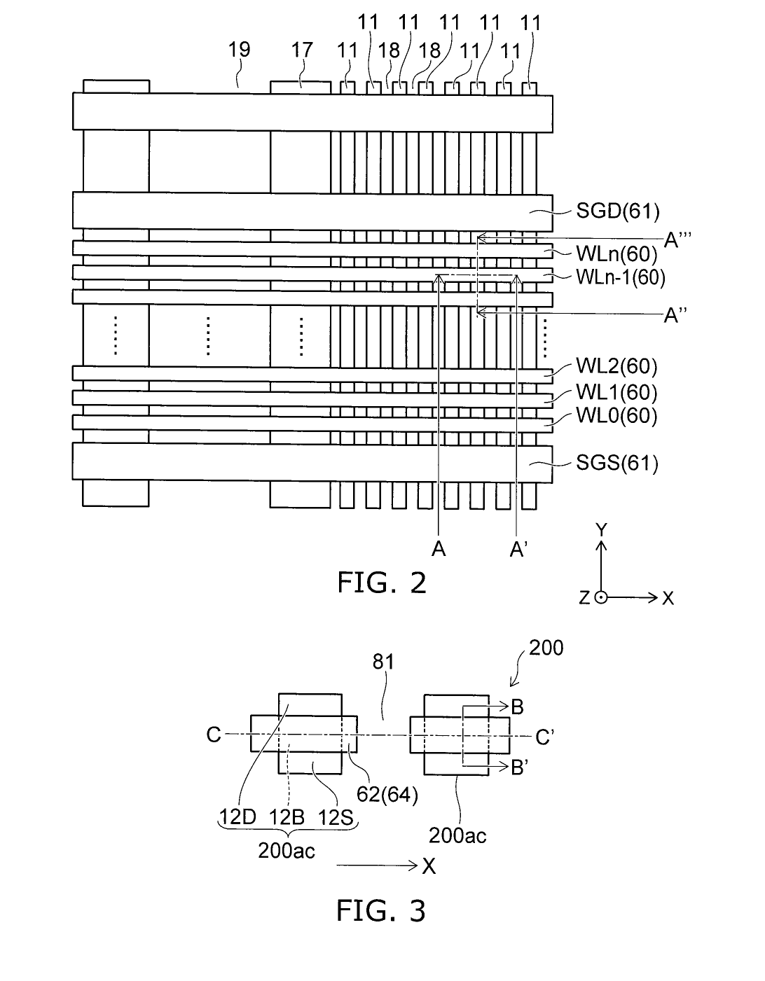

FIG. 2 is an example of a schematic plan view showing the pattern layout of the memory cell unit according to the first embodiment.

An element separation layer 19, a semiconductor region 17, and semiconductor regions 11 (element regions) are arranged in the X-direction in the semiconductor layer at the vicinity of the row-direction end portion region 100a of the memory cell unit 100. The semiconductor region 17 is, for example, a semiconductor region where dummy memory cell transistors that do not store data is disposed. An element isolation region 18 (a first element-separating insulating film) is provided between the semiconductor region 17 and the semiconductor regions 11 and between the semiconductor regions 11. Control gate electrodes 60 that have line shapes and selection gate electrodes 61 that have line shapes are provided in the X-direction (the row direction of the memory cell unit) intersecting the Y-direction in which the semiconductor regions 11 extend. The selection gate electrodes 61 include a selection gate electrode SGD of the drain side and a selection gate electrode SGS of the source side. The control gate electrodes 60 (the control gate electrodes WL0 to WLn) are interposed between the selection gate electrode SGD and the selection gate electrode SGS.

FIG. 3 is an example of a schematic plan view showing transistors of the peripheral unit according to the first embodiment.

In the peripheral unit 200, element regions 200ac are divided by an element isolation region 81 (a second element-separating insulating film). On each of the element regions, a gate electrode 62 that extends in the X-direction is disposed to extend onto the element isolation region 81. Here, the gate electrodes 62 are disposed on the same straight line in the X-direction. Each of the element regions 200ac includes a source region 12S and a drain region 12D provided on two sides of the gate electrode 62. Also, the element region 200ac includes a channel region 12B (semiconductor region 12B) in the region directly under the gate electrode 62.

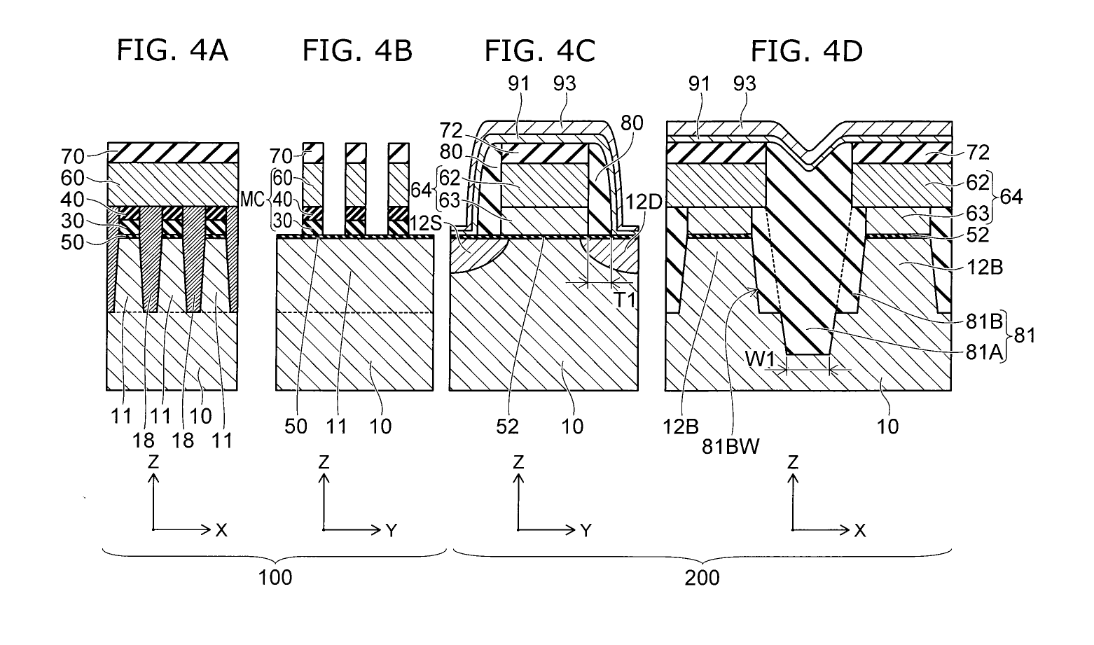

FIGS. 4A and B are examples of schematic cross-sectional views of the memory cell unit according to the first embodiment; and FIGS. 4C and D are examples of schematic cross-sectional views of a transistor of the peripheral unit.

A cross section at a position along line A-A′ of FIG. 2 is shown in FIG. 4A. A cross section at a position along line A″-A′″ of FIG. 2 is shown in FIG. 4B. A cross section at a position along line B-B′ of FIG. 3 is shown in FIG. 4C. A cross section at a position along line C-C′ of FIG. 3 is shown in FIG. 4D.

The memory cell unit 100 (the memory cell region 100) shown in FIGS. 4A and B is adjacent to the peripheral unit 200 (the peripheral region 200) shown in FIGS. 4C and D.

In the memory cell unit 100 as shown in FIG. 4A and FIG. 4B, a semiconductor layer 10 is divided into a plurality in the X-direction (the first direction) by the element isolation region 18. The divided regions are used as the semiconductor regions 11. Each of the semiconductor regions 11 extends in the Y-direction (the second direction) intersecting the X-direction. A memory cell MC is disposed above each of the semiconductor regions 11 with an insulating film 50 interposed. The memory cell MC includes a charge storage layer 30 (e.g., a charge trap layer 30), an insulating film 40 (a blocking layer 40) provided on the charge storage layer 30, and the control gate electrode 60 provided on the upper side of the insulating film 40. An insulating layer 70 (a capping layer 70) is provided above the control gate electrode 60.

The control gate electrode 60 is included in a word line WL that is shared by the memory cells adjacent to each other in the X-direction. Further, a diffusion layer may be formed in an upper portion of the semiconductor regions 11 and between the memory cells MC. Also, as shown in FIGS. 4C and D, peripheral transistors peripheral transistors are disposed in the peripheral unit 200. As shown in FIG. 4C, an insulating film 52 and a gate electrode 64 (the stacked structure of the gate electrodes 63 and 62) are included above the semiconductor layer 10. The insulating film 52 functions as a gate insulating film provided between the gate electrode 64 and the semiconductor layer 10. Here, the gate electrode 62 may include tungsten; and the gate electrode 63 may include polysilicon. An insulating layer 72 (a capping layer 72) is provided on the gate electrode 64. Also, sidewall films 80 are provided at the side surfaces of the gate electrode 64. The sidewall films 80 and the insulating layer 72 are covered with insulating films 91 and 93.

Also, as shown in FIG. 4D, the semiconductor layer 10 is divided into two semiconductor regions 12B by the element isolation region 81. The polysilicon layer 63 is provided above the semiconductor region 12B with the insulating film 52 interposed. The gate electrodes 64 are divided in the X-direction by the element isolation insulating film 81. In other words, the side surface of the gate electrode 62 contacts an element isolation region 81A in the direction in which the gate electrode 64 extends. Also, the boundary between the element isolation region 81A and the semiconductor layer 10 is positioned on a straight line from the boundary between the element isolation region 81A and the gate electrode 62. Further, the insulating films 91 and 93 are disposed to be continuous on the gate electrodes 64 in the X-direction.

Also, the element isolation region 81 includes the first element isolation region 81A (a first portion), and a second element isolation region 81B (a second portion) that is provided to be adjacent to the first element isolation region 81A in the X-direction and is provided on two sides of the first element isolation region 81A. For example, in the cross section of FIG. 4D, there is a bonding portion between the first element isolation region 81A and the second element isolation region 81B that is on a line connecting the bonding portion between the gate electrode 62 and the first element isolation region 81A and the bonding portion between the first element isolation region 81A and the semiconductor layer 10. In other words, the second element isolation region 81B is the portion of the element isolation region 81 protruding in the X-direction from the side portion of the first element isolation region 81A. A side surface 81BW of the second element isolation region 81B is positioned on the lower side of the gate electrode 64. Also, the first element isolation region 81A extends between mutually-adjacent gate electrodes 64. Further, there is a recess in an upper surface of the first element isolation region 81A. The insulating layer 72 and the element isolation region 81 are covered with the insulating films 91 and 93.

In the peripheral unit 200, a width W1 of the bottom portion of the first element isolation region 81A in the X-direction between the mutually-adjacent gate electrodes 64 is not more than about twice a thickness T1 of the sidewall film 80 at the lower end of the sidewall film 80. Here, the width W1 is defined by the width of the bottom portion of the first element isolation region 81A in the X-direction. Specifically, when the thickness T1 is 40 nm, the width W1 is 80 nm or less.

Here, when the filling of the first element isolation region 81A is considered, it is favorable for the first element isolation region 81A to have a tapered shape. For example, an impurity element such as boron (B), etc., is introduced to the semiconductor region 11 and the semiconductor region 12B. The semiconductor region 11 and the semiconductor region 12B are p-type semiconductors. For example, an impurity element such as phosphorus (P), etc., is introduced to the source region 12S and the drain region 12D. In other words, the peripheral transistor is an Nch transistor. The peripheral transistor may be a Pch transistor by introducing, for example, an impurity element such as boron (B), etc., to the source region 12S and the drain region 12D.

The charge storage layer 30 may include, for example, a stacked film of an oxynitride film or a nitride film and polysilicon. The insulating film 40 may be a stacked film of a metal oxide film and a silicon oxide film, a silicon oxide film, or a stacked film of these films. The control gate electrode 60, the gate electrode 64, and the gate electrode 62 have stacked structures of tungsten (W)/tungsten nitride (WN). The material of the sidewall film 80 includes, for example, silicon oxide.

Further, in the embodiment, the insulating films, the insulating layers, and the element isolation regions other than those recited above include one selected from silicon oxide and silicon nitride or a stacked film of silicon oxide and silicon nitride.

Manufacturing processes of the non-volatile semiconductor memory device 1 will now be described.

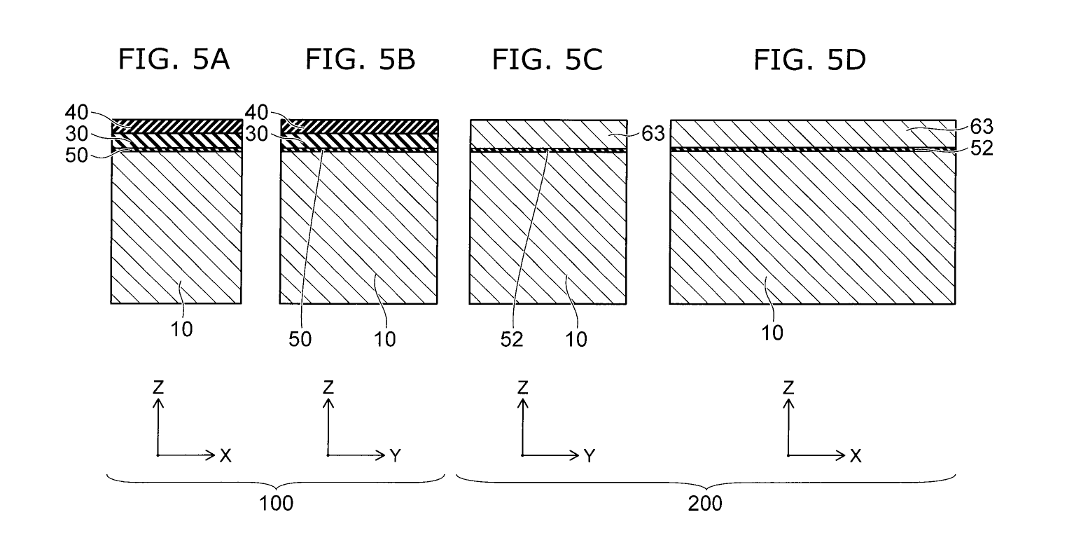

FIG. 5A to FIG. 5D are examples of schematic cross-sectional views showing the manufacturing processes of the non-volatile semiconductor memory device according to the first embodiment. FIG. 5A to FIG. 5D respectively correspond to the positions of FIG. 4A to FIG. 4D.

First, in the memory cell unit 100, the insulating film 50 is formed on the semiconductor layer 10 (the first semiconductor layer) as shown in FIGS. 5A and B.

Also, in the peripheral unit 200, the insulating film 52 is formed on the semiconductor layer 10 as shown in FIGS. 5C and D. The insulating films 50 and 52 may be formed simultaneously; and in such a case, the insulating films 50 and 52 include the same material.

Then, in the memory cell unit 100, the charge storage layer 30 is formed on the upper side of the semiconductor layer 10 as shown in FIG. 5A and FIG. 5B.

Further, in the peripheral unit 200, the polysilicon layer (the second semiconductor layer) is formed on the semiconductor layer 10 with the insulating film 52 interposed as shown in FIGS. 5C and D.

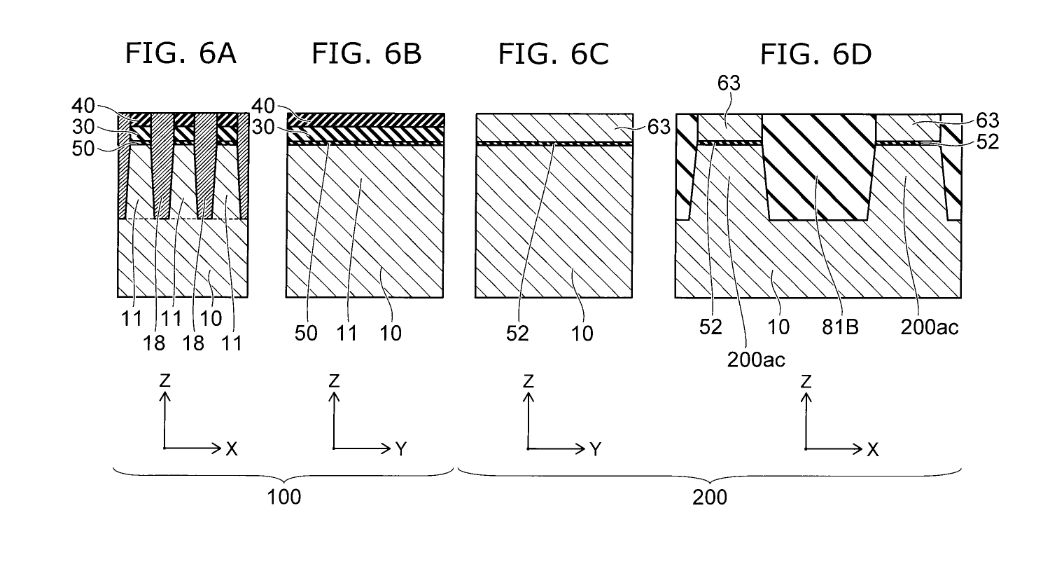

Then, in the memory cell unit 100, the semiconductor layer 10 is divided in the X-direction to form the semiconductor regions 11 extending in the Y-direction as shown in FIG. 6A. The element isolation region 18 is formed between the semiconductor regions 11.

Also, in the peripheral unit 200, the element isolation region 81B is formed in the semiconductor layer 10 as shown in FIG. 6D. Thereby, the semiconductor layer 10 is divided into the element regions 200ac by the element isolation region 81B. In the cross sections shown in FIG. 6B and FIG. 6C, the state of the previous process is maintained.

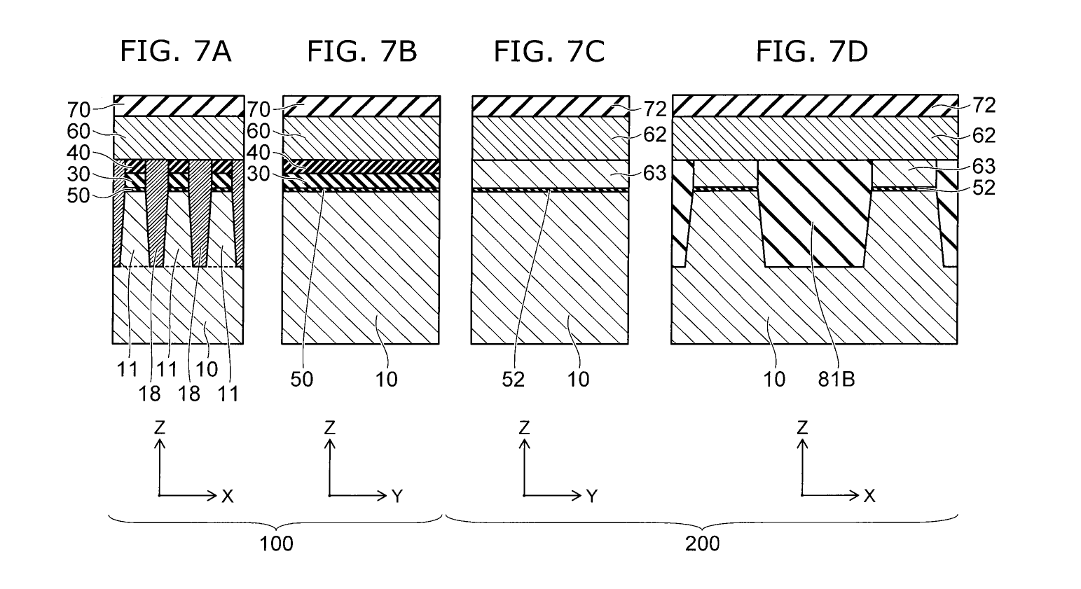

Then, in the memory cell unit 100, a conductive layer 60 is formed on the upper side of the charge storage layer 30 with the insulating film 40 interposed as shown in FIG. 7A and FIG. 7B. Further, the insulating layer 70 is formed on the conductive layer 60.

Also, in the peripheral unit 200, the gate electrode 62 is formed on the polysilicon layer 63 and on the element isolation region 81B as shown in FIGS. 7C and D. The conductive layers 60 and 62 may be formed simultaneously, and in such a case, The conductive layers 60 and 62 have the same components. The insulating layers 70 and 72 may be formed simultaneously, and in such a case, the insulating layers 70 and 72 have the same components.

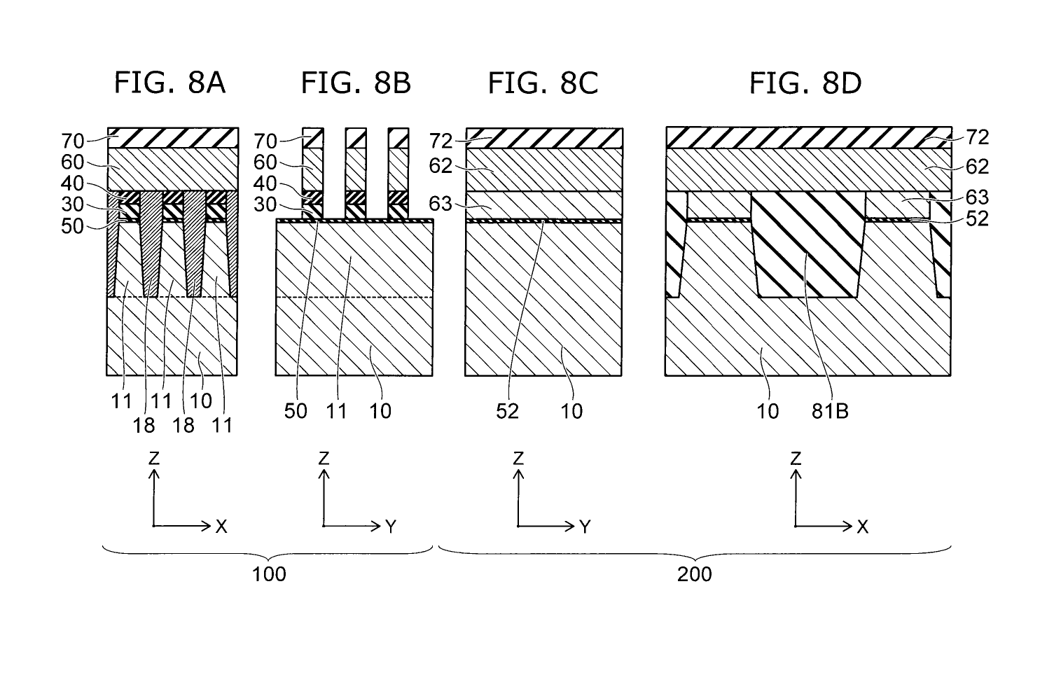

Then, in the memory cell unit 100, the conductive layer 60 is divided in the Y-direction to form the control gate electrodes 60 extending in the X-direction as shown in FIG. 8B.

As a result, the charge storage layers 30 are formed between each of the semiconductor regions 11 and each of the control gate electrodes 60.

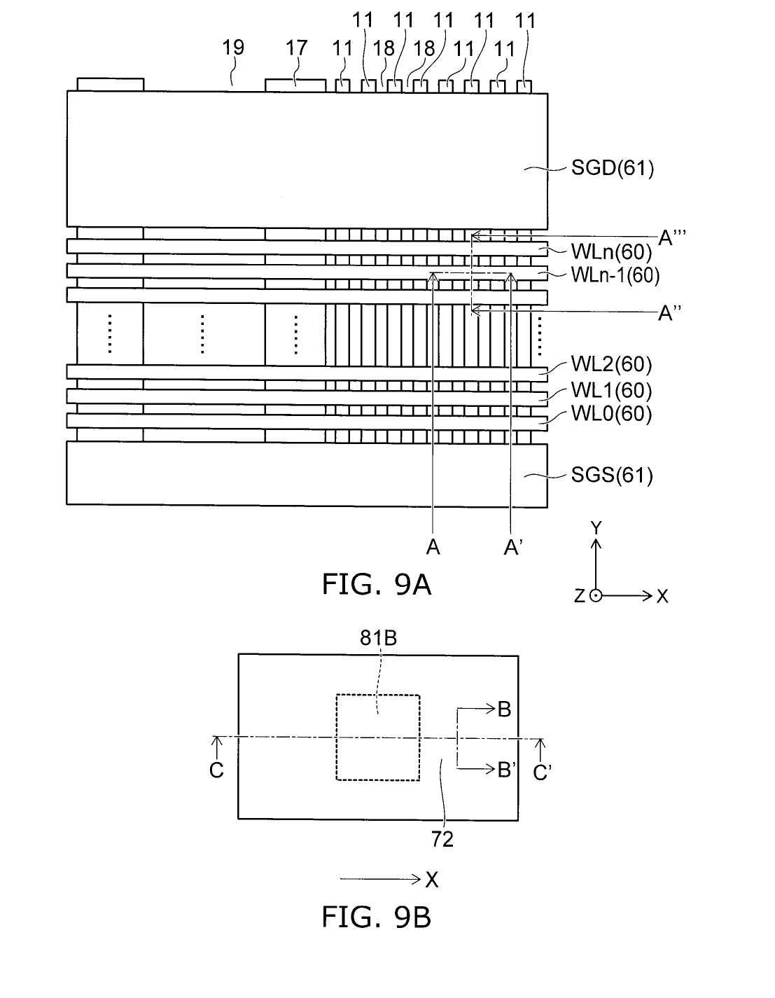

FIGS. 9A and B show schematic plan views after the processes shown in FIG. 8A to FIG. 8D.

Also, lines A-A′ and A″-A′″ illustrated in FIG. 2 and B-B′ and C-C′ of FIG. 3 are illustrated in the drawings.

As shown in FIGS. 9A and B, the patterning of the control gate electrodes 60 is performed; but the patterning of the selection gate electrodes SGD and SGS is not performed.

The subsequent manufacturing processes of the non-volatile semiconductor memory device will now be described using plan views in addition to the cross-sectional views.

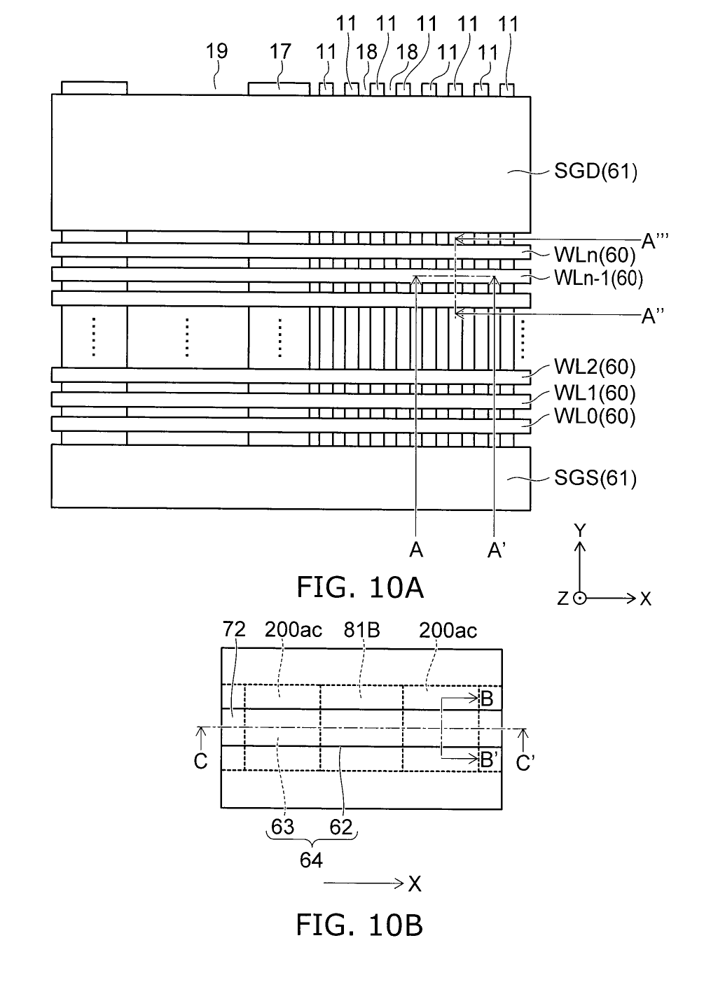

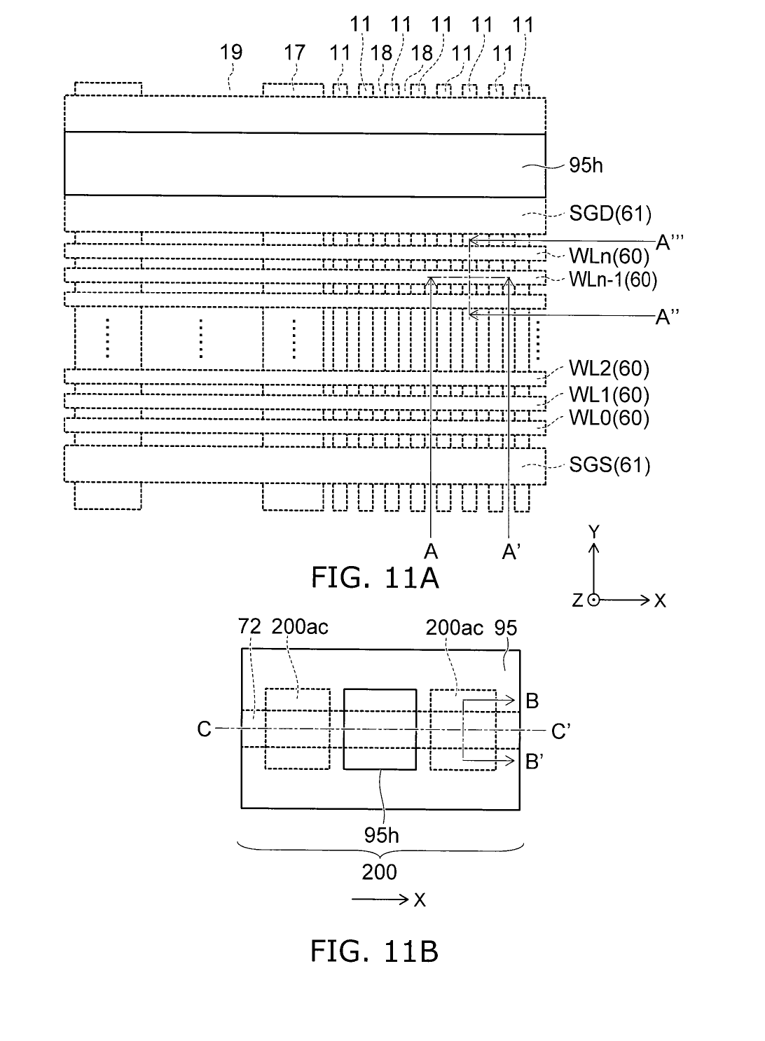

FIG. 10A to FIG. 11B are examples of schematic plan views showing the manufacturing processes of the non-volatile semiconductor memory device according to the first embodiment. The drawings respectively correspond to the positions of FIGS. 9A and B.

Then, in the peripheral unit 200, etching of the insulating layer 72 and the gate electrode 62 is performed to form the gate electrode 64 having a linear configuration that straddles two element regions 200ac in the X-direction as shown in FIG. 10B. At this time, the etching is RIE (Reactive Ion Etching), etc. Although the two element regions 200ac are shown in FIG. 10B, the number of the element regions 200ac is not limited to two. In the peripheral unit 200, two or more element regions 200ac may be provided; and the gate electrode 64 may be formed to straddle two or more the element regions 200ac. At this stage, patterning of the selection gate electrodes 61 is not performed. In other words, the widths of the selection gate electrodes 61 in the Y-direction are the same as those of FIG. 9A.

In the memory cell unit 100, a mask layer 95 for forming the selection gate electrodes is formed on the insulating layer 70 as shown in FIG. 11A. Also, in the peripheral unit 200, the mask layer 95 for subdividing the gate electrode 64 and patterning the second element isolation region 81B under the gate electrode 64 and the semiconductor layer 10 under the second element isolation region 81B is formed as shown in FIG. 11B. An opening 95h is provided in the mask layer 95. The opening 95h is provided between the element regions 200ac adjacent to each other and above the gate electrode 64. When viewed in the top view, the opening 95h is wider than the width of the gate electrode 64 and is disposed not to overlap the element regions 200ac.

Then, as shown in FIG. 11A, the selection gate electrode 61 is divided in the Y-direction to form the selection gate electrodes 61. For example, a resist mask is formed in which substantially the central portion of the selection gate electrode 60 in the Y-direction shown in FIG. 10A recited above has an opening 95h that is continuous in the X-direction.

Simultaneously, the resist mask also is formed in the peripheral region 200. As shown in FIG. 11B, the opening 95h is made in the resist mask on the element isolation region 81 between the element regions 200ac. The opening 95h is disposed to divide the gate electrode 64 having the linear configuration that straddles the two element regions 200ac. Specifically, the width of the opening 95h in the Y-direction is wider than the width of the gate electrode 64 in the Y-direction; and the opening 95h is disposed to include the gate electrode 64. Here, the lithography margin is taken into consideration to set the opening 95h not to overlap the element regions 200ac.

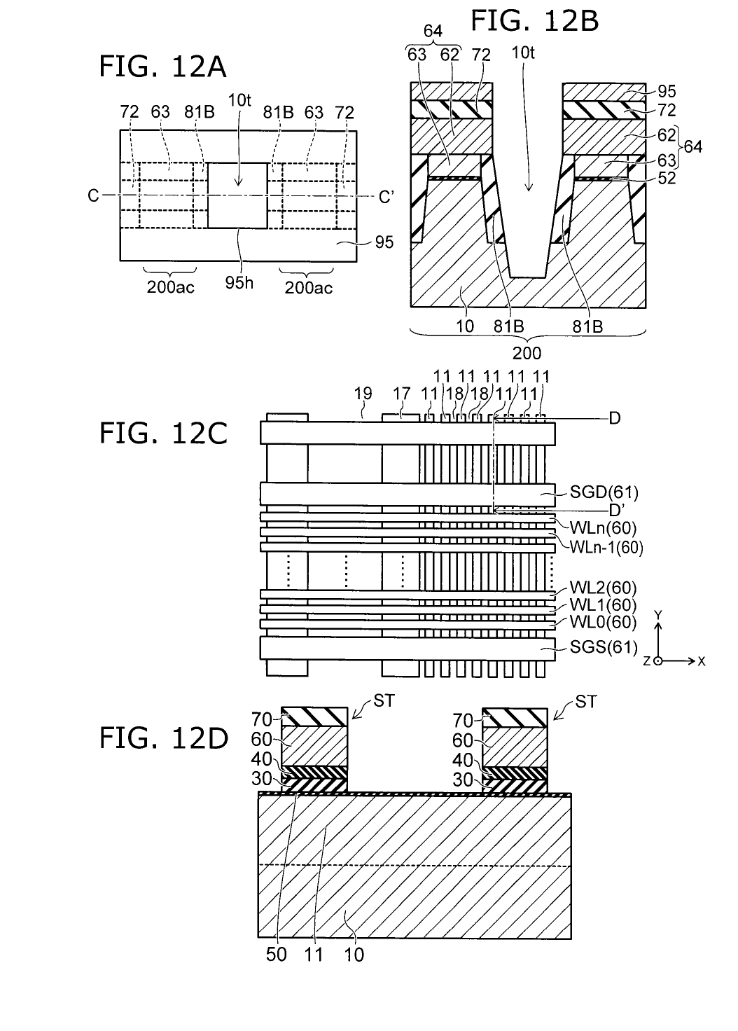

FIGS. 12A and 12C are examples of schematic plan views showing the manufacturing processes of the non-volatile semiconductor memory device according to the first embodiment; and FIG. 12B and FIG. 12D are examples of schematic cross-sectional views showing the manufacturing processes of the non-volatile semiconductor memory device according to the first embodiment. FIG. 12A to FIG. 12D are drawings showing the state after FIG. 11B; and FIG. 12B is the C-C′ cross section of FIG. 12A. FIG. 12D is the D-D′ cross section of FIG. 12C.

Then, in the memory cell unit 100, the insulating layer 70, the conductive layer 60, the insulating film 40, and the charge storage layer 30 that are exposed at the opening 95h are removed as shown in FIGS. 12C and D. Simultaneously, in the peripheral unit 200, the gate electrode 64 having the linear configuration that is positioned between the two element regions 200ac exposed at the opening 95h, the second element isolation region 81B that is under the gate electrode 64, and the semiconductor layer 10 that is under the second element isolation region 81B are removed to make a trench 10t as shown in FIG. 12A and FIG. 12B. As a result, the electrodes of selection gate transistors ST can be formed; and the semiconductor layer 10 that is under the second element isolation region 81B can be excavated downward. Here, the side surface of the semiconductor layer 10 that is exposed in the trench 10t, the side surface of the second element isolation region 81B that is exposed in the trench 10t, and the side surface of the gate electrode 62 that is exposed in the trench 10t are a continuous plane.

Here, fine patterning by so-called sidewall patterning, etc., is unnecessary because the space between the gate electrodes of the selection gate transistors is wider than the space between the memory cells MC. Similarly, in the peripheral unit 200 as well, fine patterning by so-called sidewall patterning, etc., is unnecessary because the space between the gate electrodes 64 of the peripheral transistors is wider than the space between the memory cells MC. As a result, the patterning of the gate electrodes of the selection gate transistors can be performed simultaneously with the patterning of the gate electrodes 64 of the peripheral transistors of the peripheral unit 200.

At this point, the etching in the process shown in FIGS. 12A and B is, for example, RIE. In the process shown in FIGS. 12A and B and the etching of the gate electrodes 64 in the memory cell unit 100 may progress simultaneously. At this time, by adjusting the selectivity of the etching rate, the semiconductor layer 10 that is under the second element isolation region 81B can be etched downward while forming the gate electrodes of the selection gate transistors ST in the memory cell unit 100.

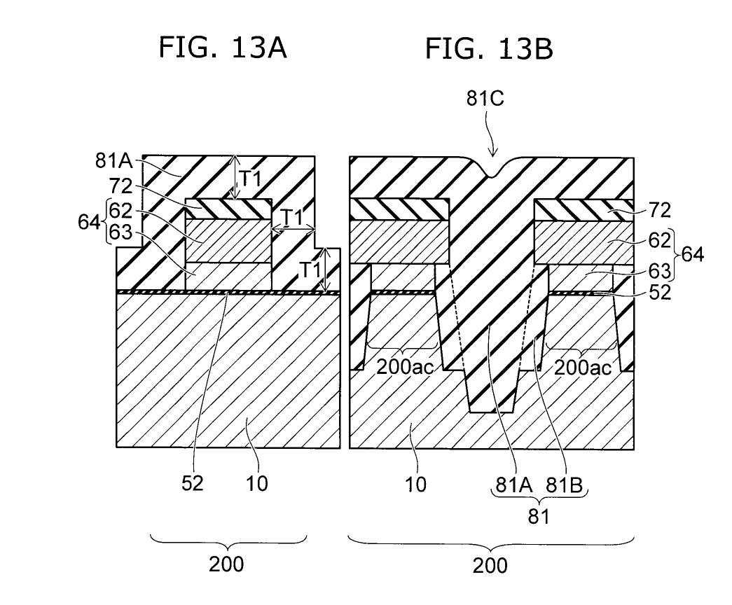

FIG. 13A and FIG. 13B are examples of schematic cross-sectional views showing the manufacturing processes of the non-volatile semiconductor memory device according to the first embodiment. FIGS. 13A and B are drawings showing the state after FIG. 12B. Here, FIG. 13A is the B-B′ cross section; and FIG. 13B is the C-C′ cross section.

Then, the insulating film 81A is deposited in the entire region of the peripheral unit 200. At this time, the insulating film 81A can be deposited in the memory cell unit 100 as well.

Here, the insulating film 81A is deposited to have the thickness T1. Here, the thickness T1 is adjusted to be not less than about ½ times the width W1 of the bottom portion of the trench 10t. As a result, the trench 10t is filled with the insulating film 81. Also, the insulating film 81A can include the same material as the insulating film 81B.

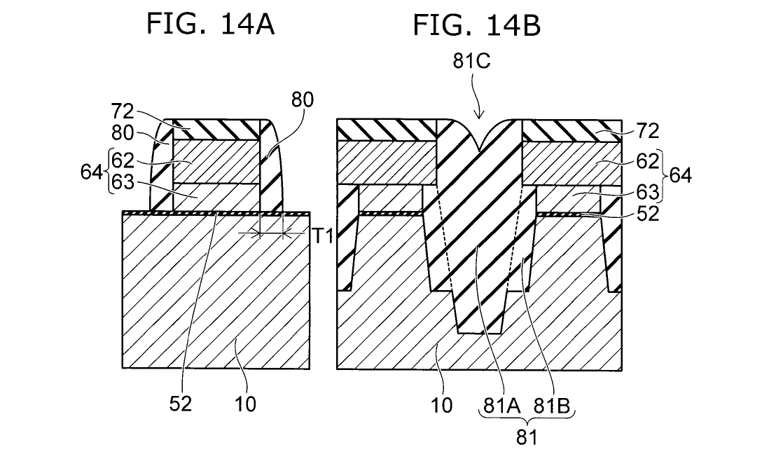

FIG. 14A and FIG. 14B are examples of schematic cross-sectional views showing the manufacturing processes of the non-volatile semiconductor memory device according to the first embodiment. FIG. 14A is a drawing showing the state after FIG. 13A; and FIG. 14B is a drawing showing the state after FIG. 13B.

Then, as shown in FIG. 14A, etch-back of the insulating film 81A is performed by, for example, anisotropic dry etching. By the etch-back, the insulating film 81A remains as the sidewall film 80 on the side surface of the insulating layer 72 and on the side surface of the selection gate electrode 64.

Also, as shown in FIG. 14B, the etch-back is performed by the dry etching until the upper surface of the insulating layer 72 is exposed from the first element isolation region 81A. At this time, the upper surface of a recess 81C is maintained and is etched-back to near the upper portion of the insulating layer 72. As a result, the recess 81C remains in the upper surface of the first element isolation region 81A.

Subsequently, the drain diffusion layer of the selection gate transistor is formed by ion implantation of, for example, an n-type impurity into the semiconductor layer 10 using the sidewall film 80 and the selection gate electrode 64 as a mask.

Then, subsequently, as shown in FIG. 4C, the insulating films 91 and 93 are formed on the sidewall film 80 and the upper side of the gate electrode 64. Also, as shown in FIG. 4D, the insulating films 91 and 93 are formed on the first element isolation region 81A and the upper side of the gate electrode 64.

Before describing effects of the first embodiment, manufacturing processes according to a reference example will be described.

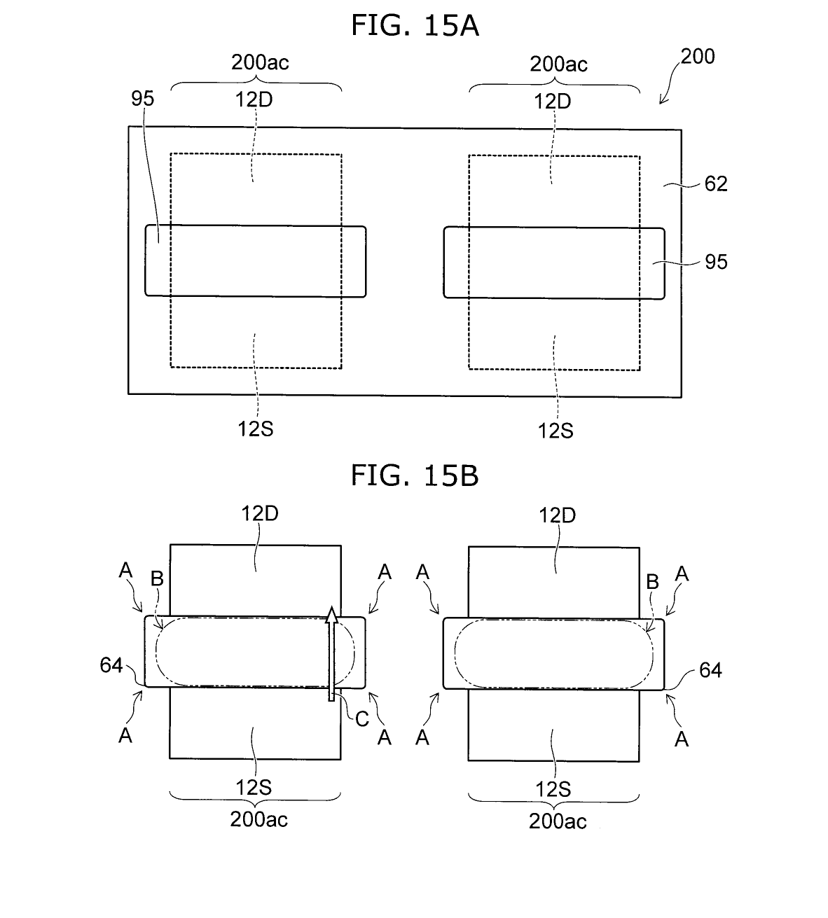

FIG. 15A and FIG. 15B are schematic plan views showing the manufacturing processes of the non-volatile semiconductor memory device according to a comparative example.

For example, as shown in FIG. 15A, the mask layer 95 for forming the gate electrode 64 is patterned on the gate electrode 62. Subsequently, the gate electrodes 64 that reflect the mask pattern are formed by performing RIE of the gate electrode 62. This state is shown in FIG. 15B.

However, generally, the corners (the locations illustrated by arrows A) of the gate electrode 64 that reflect the mask pattern are etched easily.

Therefore, the corners of the gate electrode 64 are affected easily by the etching; and there is a possibility that the corners may be rounded undesirably (the configuration illustrated by arrows B in FIG. 15B). Also, in the lithography as well, there is a tendency for the corners of the resist used to form the mask of the gate electrodes 64 to be rounded.

Here, when the rounding of the corners of the gate electrode 64 becomes large, the length of the gate electrode 64 at the element region 200ac end portion becomes short (this is called shortening). The shortening easily occurs when the gate electrode is shrunk.

As a result, in the peripheral unit 200, there is a possibility that the characteristics of an I_{off} state of the transistor may degrade. For example, the increase of the I_{off} value when the transistor turns OFF. Also, there is a possibility that punch-through between the source-drain may occur. For example, there is a possibility that punch-through may occur between the source-drain (between 12D-12S) at the portion where the width of the gate electrode 64 of the element region end portion is short (arrow C of FIG. 15B).

Conversely, in the first embodiment as shown in FIG. 10, the gate electrode 64 having the linear shape is formed; and subsequently, the gate electrode 64 having the linear shape, the second element isolation region 81B under the gate electrode 64, and the semiconductor layer 10 under the second element isolation region 81B are etched collectively.

Thereby, the corners of the gate electrode 64 are not exposed in the etching of the first etching (FIG. 10). As a result, the corners of the gate electrode 64 are not rounded easily in the second RIE (FIGS. 12A and B). As a result, the shortening of the gate electrode 64 does not occur easily. As a result, the transistor characteristics when the transistor turns OFF do not degrade easily; and the leak current is suppressed.

In other words, the corners of the gate electrode 64 are not rounded easily because the patterning of the gate electrode 64 is equivalent to performing patterning twice using resist patterns having linear configurations.

Also, in the peripheral unit 200, the first element isolation region 81A that is deeper than the second element isolation region 81B is formed between the mutually-adjacent element regions 200ac. Thereby, between the mutually-adjacent element regions 200ac as well, the leak current is suppressed.

Further, in the peripheral unit 200, the width W1 of the bottom portion of the first element isolation region 81A is adjusted to be not more than about twice the thickness T1 of the sidewall film 80 at the lower end of the sidewall film 80. For example, in the case where the width W1 is greater than twice the thickness T1, there is a possibility that the first element isolation region 81A may no longer be sufficiently filled into the trench 10t. In such a case, there is a possibility that the impurity element may be implanted into the semiconductor layer 10 on the lower side of the element isolation region 81 when performing the ion implantation of, for example, the n-type impurity in the diffusion layer formation process of the selection gate transistor. As a result, it may not suppress the punch-through between the mutually-adjacent element regions 200ac. Moreover, in the case where the width W1 is greater than twice the thickness T1, the lower portion of the recess 81C of the element isolation region 81 is lower. Thereby, the planarization of the layers stacked on the upper layer of the element isolation region 81 may become difficult.

Accordingly, it is preferable to adjust the width W1 of the bottom portion of the first element isolation region 81A to be not more than twice the thickness T1 of the sidewall film 80 at the lower end of the sidewall film 80.

### Second Embodiment

A modification of the method for forming the gate electrode in the peripheral unit 200 will now be described.

In the second embodiment, the gate electrode 64 having the linear configuration is formed beforehand between two element regions 200ac as shown in FIGS. 10A and B. The manufacturing processes of the second embodiment will now be described.

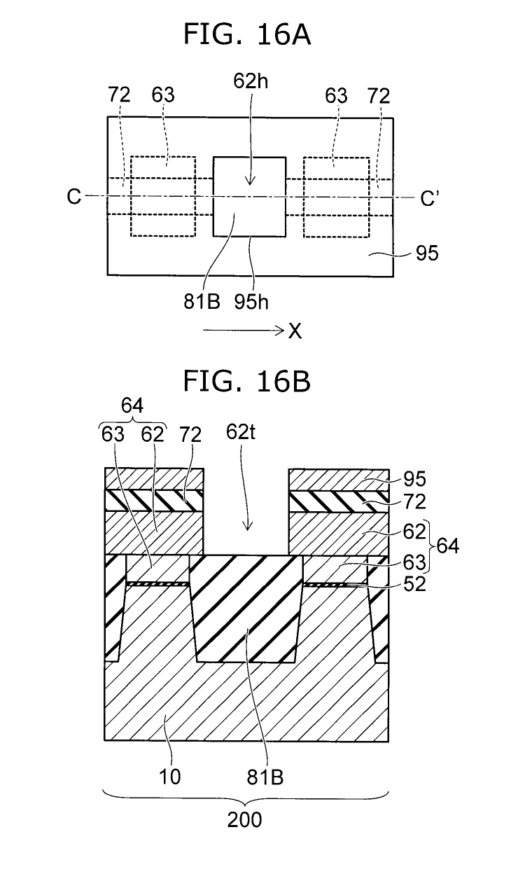

FIG. 16A is an example of a schematic plan view showing the manufacturing processes of the non-volatile semiconductor memory device according to the second embodiment; and FIG. 16B is an example of a schematic cross-sectional view.

FIG. 16A and FIG. 16B are drawings showing the peripheral unit 200; for example, FIG. 16A is a drawing corresponding to the position of FIG. 12A of the first embodiment; and FIG. 16B is a drawing corresponding to the position of FIG. 12B of the first embodiment.

In the peripheral unit 200, the gate electrode 64 having the linear configuration that is positioned between the two element regions 200ac exposed at the opening 95 is etched as shown in FIG. 16A and FIG. 16B. Here, the element isolation region 81B substantially is not etched. Thereby, the gate electrode 64 having the linear configuration is divided for the two element regions 200ac. By the etching, a trench 62t is made between the mutually-adjacent gate electrodes 64.

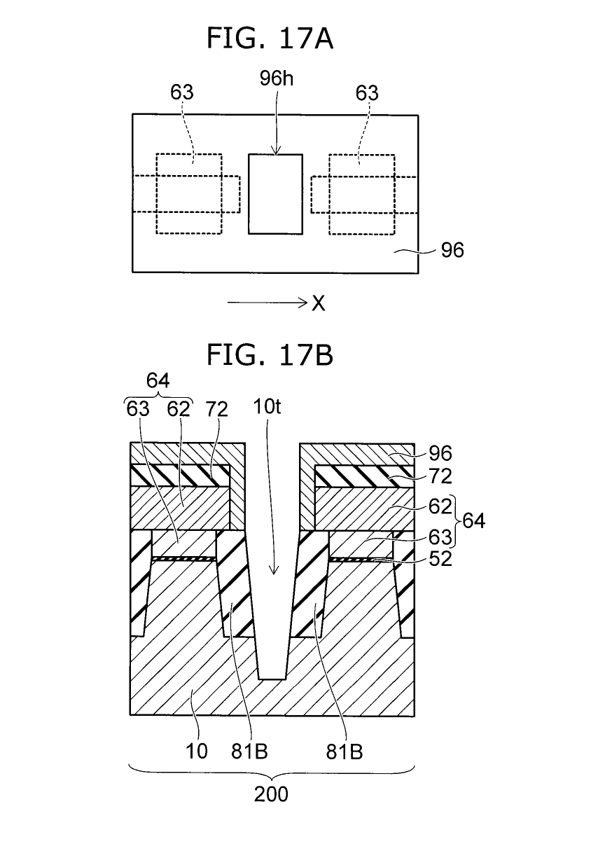

FIG. 17A is an example of a schematic plan view showing the manufacturing processes of the non-volatile semiconductor memory device according to the second embodiment; and FIG. 17B is an example of a schematic cross-sectional view. Here, FIG. 17A is a drawing showing the state after FIG. 16A; and FIG. 17B is a drawing showing the state after FIG. 16B.

Then, in the peripheral unit 200, a mask layer 96 (e.g., a photoresist) is formed to cover the side surface of the gate electrode 62, the upper surface, and side surfaces of the insulating layer 72. An opening 96h is provided in the mask layer 96. Here, the width of the opening 96h in the X-direction is narrower than the width of an opening 62h in the X-direction. Then, as shown in FIG. 17A and FIG. 17B, the trench 10t is made from the semiconductor layer 63 to reach the semiconductor layer 10 by etching the semiconductor layer 63 between the subdivided gate electrodes 64 exposed at the opening 96h, the second element isolation region 81B under the semiconductor layer 63, and the semiconductor layer 10 under the second element isolation region 81B. Here, the side surface of the semiconductor layer 10 that is exposed in the trench 10t, the side surface of the second element isolation region 81B that is exposed in the trench 10t, and the side surface of the mask layer 96 are continuous.

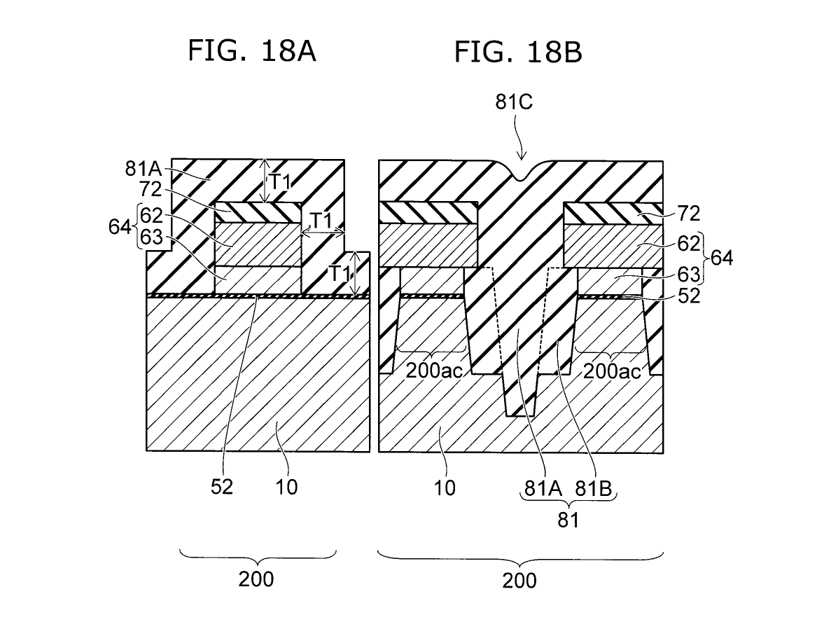

This process can be performed simultaneously with the patterning of the selection gate electrodes 64 in FIGS. 11 and 12 of the first embodiment. FIGS. 18A and B are drawings showing the state after FIG. 17B; FIG. 18A corresponds to the B-B′ cross section; and FIG. 18B corresponds to the C-C′ cross section.

Then, in the entire region of the peripheral unit 200 as shown in FIG. 18A, the insulating film 81A is formed to surround the insulating layer 72 and the selection gate electrode 64. At this time, the insulating film 81A may be deposited in the memory cell unit 100 as well. Here, the insulating film 81A is deposited to have the thickness T1. Here, the thickness T1 is adjusted to be not less than about ½ times the width W1 of the bottom portion of the trench 10t. As a result, the trench 10t is filled with the insulating film 81. Also, the insulating film 81A can include the same material as the insulating film 81B.

That is, as shown in FIG. 18B, the first element isolation region 81A is formed on the insulating layer 72, inside the trench 10t, and surround the gate electrodes 64. Thereby, the element isolation region 81 that includes the first element isolation region 81A and the second element isolation region 81B is formed. The element isolation region 81 is formed between the adjacent to element regions 200ac each other. In the first embodiment, a stepped portion occurs at the first element isolation region 81A and the second element isolation region 81B because the first element isolation region 81A and the second element isolation region 81B are formed separately from each other. Also, the recess 81C remains in the upper surface of the first element isolation region 81A because the first element isolation region 81A is formed inside the trench 10t that is deep.

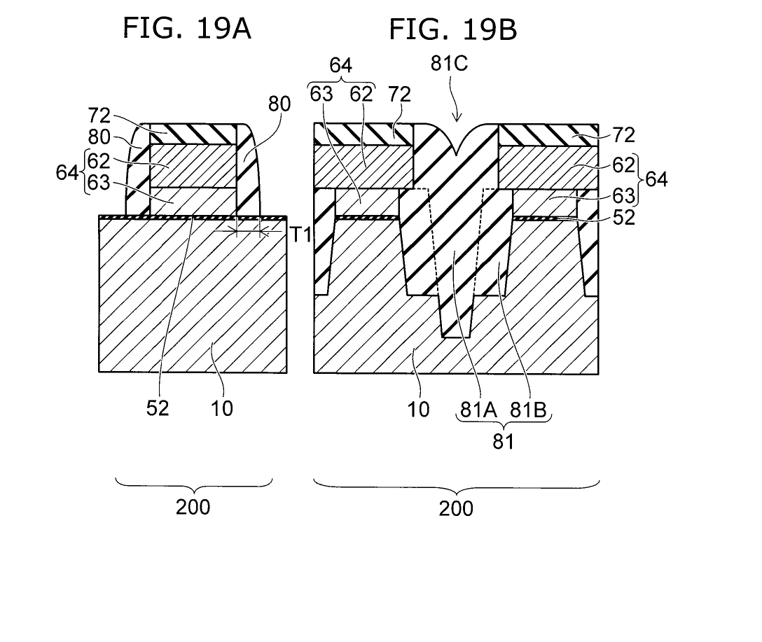

FIG. 19A is a drawing showing the state after FIG. 18A; and FIG. 19B is a drawing showing the state after FIG. 18B.

Then, as shown in FIG. 19A, etch-back of the insulating film 81A is performed by dry etching. By the etch-back, the insulating film 81A remains as the sidewall film 80 at the side surface of the insulating layer 72 and at the side surface of the selection gate electrode 64.

As a result, as shown in FIG. 19B, the upper surface of the insulating layer 72 is exposed from the first element isolation region 81A by the dry etching. Also, in the etch-back, the shape of the recess 81C is maintained and is etched-back to the upper portion vicinity of the insulating layer 72. Thereby, the recess 81C remains in the upper surface of the first element isolation region 81A.

Thus, in the peripheral unit 200, the sidewall film 80 is formed at the side surface of the selection gate electrode 64 simultaneously with the first element isolation region 81A being formed inside the trench 10t. Subsequently, the drain diffusion layer of the selection gate transistor is formed by performing ion implantation of, for example, an n-type impurity using the sidewall film 80 and the selection gate electrode 64 as a mask.

Further, subsequently, the insulating films 91 and 93 are formed on the sidewall film 80 and the above the gate electrode 64 as shown in FIG. 4C. Further, as shown in FIG. 4D, the insulating films 91 and 93 are formed above the first element isolation region 81A and the upper side of the gate electrode 64.

In the embodiment, the distance between the gate electrodes 63 in the X-direction and the width of the bottom portion of the trench 10t can be adjusted independently from each other. In other words, the width of the bottom portion of the trench 10t can be set to be not more than ½ of the film thickness of the sidewall film 80 by adjusting the width of the opening 96h even in the case where the distance between the gate electrodes 63 is not less than ½ of the film thickness of the sidewall film 80.

In the second embodiment as well, the same effects as the first embodiment are obtained.

### Third Embodiment

Other than an ONO structure, the non-volatile semiconductor memory device of the embodiment may have a floating gate structure.

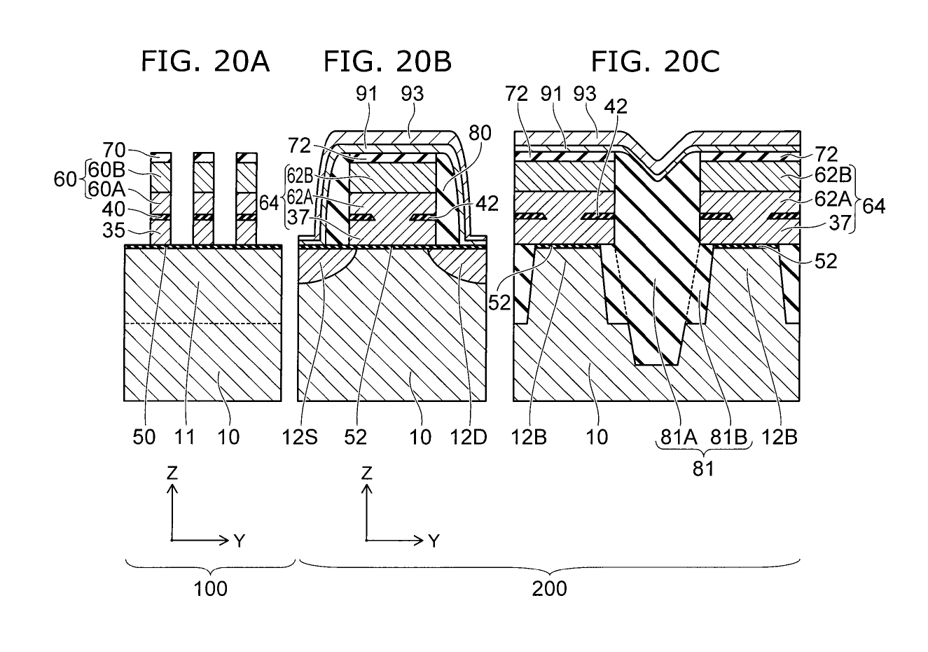

FIG. 20A is an example of a schematic cross-sectional view of the memory cell unit according to the third embodiment; and FIGS. 20B and C are examples of schematic cross-sectional views of the transistor of the peripheral unit.

The cross section at a position along line A″-A′″ of FIG. 2 is shown in FIG. 20A. The cross section at a position along line B-B′ of FIG. 3 is shown in FIG. 20B. The cross section at a position along line C-C′ of FIG. 3 is shown in FIG. 20C.

In the memory cell unit 100 as shown in FIG. 20A, a charge storage layer 35 is provided on the upper side of the semiconductor region 11 with the insulating film 50 interposed. The insulating film 40 is provided on the charge storage layer 35. The control gate electrode 60 is provided on the upper side of the insulating film 40. The control gate electrode 60 includes a conductive layer 60A and a conductive layer 60B.

Also, in the peripheral unit 200 as shown in FIG. 20B, a conductive layer 37 is provided on the semiconductor layer 10 with the insulating film 52 interposed. An insulating film 42 is provided on the conductive layer 37. A conductive layer 62A is provided on the insulating film 42. A portion of the insulating film 42 has an opening; and the conductive layer 62A is electrically connected to the conductive layer 37. A conductive layer 62B is provided on the conductive layer 62A.

Further, in the peripheral unit 200 as shown in FIG. 20C, the conductive layer 37 is provided on the semiconductor region 12B with the insulating film 52 interposed. The insulating film 42 is provided on the conductive layer 37. The conductive layer 62A is provided on the insulating film 42. A portion of the insulating film 42 has an opening; and the conductive layer 37 is electrically connected to the conductive layer 62A.

In the peripheral unit 200, the conductive layer 37, the conductive layer 62A, and the conductive layer 62B are used as the gate electrode 64.

The insulating films 50 and 52 function as gate insulating films.

The materials of the charge storage layer 35, the conductive layer 37, the conductive layer 60A, and the conductive layer 62A are, for example, a semiconductor including a p-type impurity, a metal, a metal compound, etc. The material of the charge storage layer 30 includes, for example, amorphous silicon (a-Si), polysilicon (poly-Si), silicon-germanium (SiGe), etc.

Also, the materials of the conductive layer 60B and the conductive layer 62B are, for example, a semiconductor including a p-type impurity. The semiconductor may include polysilicon. Or, the materials of the conductive layer 60B and the conductive layer 62B may be, for example, a metal such as tungsten, etc., or a metal silicide.

According to the third embodiment, the charge storage layer 35 and the conductive layer 37 can be formed in the same process. Also, the insulating films 40 and 42 can be formed in the same process. Further, the conductive layer 60A and the conductive layer 62A can be formed in the same process. Moreover, the conductive layer 60B and the conductive layer 62B can be formed in the same process.

Accordingly, in addition to the effects of the first embodiment, a reduction of the manufacturing processes can be realized in the third embodiment. Thereby, the manufacturing cost can be reduced further.

Although the transistor of the peripheral unit 200 is illustrated in the embodiments (the first to third embodiments), this is not limited to this example. The embodiment also is applicable to other elements to suppress punch-through. Thereby, the distance between the active regions included in the non-volatile semiconductor memory device can be shortened. As a result, the chip size is reduced further.

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments. The components included in the above examples and the layout, material, condition, shape, size and the like thereof are not limited to those illustrated, but can be appropriately modified.

The term “on” in “a portion A is provided on a portion B” refers to the case where the portion A is provided on the portion B such that the portion A is in contact with the portion B and the case where the portion A is provided above the portion B such that the portion A is not in contact with the portion B. The term “upside” in “a portion A is provided upside a portion B” refers to the case where the portion A is provided upside the portion B such that the portion A is in contact with the portion B and the case where the portion A is provided above the portion B such that the portion A is not in contact with the portion B.

Furthermore, the components included in the above embodiments can be combined as long as technically feasible. Such combinations are also encompassed within the scope of the embodiments as long as they include the features of the embodiments. In addition, those skilled in the art could conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A non-volatile semiconductor memory device, comprising:
a memory cell including a charge storage layer, a control gate electrode, and first semiconductor regions of a semiconductor layer divided in a first direction by a first element isolation insulating film, the first semiconductor regions extending in a second direction intersecting the first direction, the charge storage layer being provided above the first semiconductor regions, the control gate electrode being provided above the charge storage layer;
a selection gate transistor including a selection gate electrode disposed above the first semiconductor regions with an insulating film;
peripheral transistors including a second element isolation insulating film, a gate electrode, and a diffusion layer region, the second element isolation insulating film being configured to divide the semiconductor layer into at least two second semiconductor regions, the diffusion layer region being formed in the second semiconductor regions to be provided on two sides of the gate electrode; and
a sidewall film provided at a side surface of the gate electrode,
the second element isolation insulating film having a first portion and a second portion, the second portion being provided on two sides of the first portion,
a width of a bottom portion of the first portion in an extension direction of the gate electrode being not more than twice a thickness of the sidewall film at a lower end of the sidewall film.

2. The device according to claim 1, wherein at least a part of the second portion is positioned on a lower side of the gate electrode.

3. The device according to claim 1, wherein a bottom surface of the first portion is lower than a bottom surface of the second portion.

4. The device according to claim 1, wherein
the gate electrodes provided on the at least two second semiconductor regions is positioned on a straight line in the extension direction of the gate electrode, and
the first portion is positioned between the gate electrodes.

5. The device according to claim 1, wherein the first portion and a side surface of the gate electrode are in contact.

6. The device according to claim 5, wherein a boundary between the first portion and the semiconductor layer is positioned on a straight line from a boundary between the first portion and the gate electrode.

7. The device according to claim 1, wherein a distance between the gate electrodes in the extension direction of the gate electrode is not less than twice a film thickness of the sidewall film.

8. A method for manufacturing a non-volatile semiconductor memory device, comprising:
forming a first element isolation region in a memory cell region to divide a semiconductor layer into first element regions;
forming a second element isolation region in a peripheral region to divide the semiconductor layer into at least two second element regions, the peripheral region being adjacent to the memory cell region;
forming a first conductive layer on the first element regions in the memory cell region;
forming a second conductive layer on the second element regions and the second element isolation region in the peripheral region;
performing etching of the second conductive layer to form a gate electrode in the peripheral region to straddle the at least two second element regions of the second element regions;
performing, in the peripheral region, etching of the gate electrode having the linear configuration positioned between the at least two second element regions, the second element isolation region under the gate electrode, and the semiconductor layer under the second element isolation region to divide the gate electrode having the linear configuration for the two second element regions, and to form a trench in the semiconductor layer; and
forming a first insulating film inside the trench.

9. The method according to claim 8, wherein the forming of the first insulating film includes:
depositing the first insulating film in the memory cell region and the peripheral region; and
performing etch-back of the first insulating film to simultaneously form the first insulating film inside the trench and form a sidewall film at a side wall of the gate electrode.

10. The method according to claim 8, wherein the dividing of the gate electrode having the linear configuration for the two second element regions includes simultaneously patterning the first conductive layer of the memory cell region.

11. A method for manufacturing a non-volatile semiconductor memory device, comprising:
forming a first element isolation region in a memory cell region to divide a semiconductor layer into a plurality of first element regions;
forming a second element isolation region in a peripheral region to divide the semiconductor layer into at least two second element regions, the peripheral region being adjacent to the memory cell region;
forming a first conductive layer on the first element regions in the memory cell region;
forming a second conductive layer on the second element regions and the second element isolation region in the peripheral region;
performing etching of the second conductive layer to form a gate electrode in the peripheral region to straddle the at least two second element regions of the plurality of second element regions;
dividing the gate electrode between the two second element regions in the peripheral region for at least two of the second element regions;
forming mask layer on a side surface of divided the gate electrode in the peripheral region;
in the memory cell region, forming a selection gate electrode, and in the peripheral region, etching of the second element isolation region and the semiconductor layer by using mask layer to make a trench in the semiconductor layer; and
forming a third element isolation region inside the trench and between the subdivided gate electrodes.

12. The method according to claim 11, wherein the third element isolation region is formed inside the trench simultaneously to a sidewall film being formed at a side wall of the gate electrode in the peripheral region.
